(19) United States
(12) Patent Application Publication
(10) Pub. No.: US 2005/0233484 A1
(43) Pub. Date: Oct. 20, 2005

(54) Radiation-emitting semiconductor chip and method for the production thereof

(75) Inventors: Wilhelm Stein, Lindau (DE); Johannes Volkl, Erlangen (DE); Robert Walter, Parsberg (DE); Oliver Kus, Burglengenfeld (DE); Roland Zeisel, Tegernheim (DE)

Correspondence Address: COHEN, PONTANI, LIEBERMAN & PAVANE, Suite 1210, 551 Fifth Avenue, New York, NY, 10176, US

(73) Assignee: Osram Opto Semiconductors GmbH, Regensburg (DE)

(21) Appl. No.: 11/068,599

(22) Filed: Feb. 28, 2005

(30) Foreign Application Priority Data
Feb. 27, 2004 (DE) 10 2004 009 624.4
Jun. 18, 2004 (DE) 10 2004 029 412.7

(51) Int. Cl. H01L 21/00

(52) U.S. Cl. 438/22

(57) ABSTRACT

A radiation-emitting semiconductor chip (1) having a semiconductor layer sequence (3) comprising at least one active layer (2) that generates an electromagnetic radiation, and having a passivation layer (12) arranged on the radiation-emerging side of the semiconductor layer sequence (3), it being possible to set the degree of transmission of the semiconductor chip by means of the passivation layer.

### RELATED APPLICATIONS

This patent application claims the priority of the German patent applications DE 10 2004 009624.4 of 27 Feb. 2004 and DE 10 2004.029412.7 of Jun. 18, 2004, the disclosure content of which is hereby explicitly incorporated by reference in the present patent application.

### FIELD OF THE INVENTION

The invention relates to a radiation-emitting semiconductor chip having a semiconductor layer sequence comprising at least one active layer that generates an electromagnetic radiation, and having a passivation layer arranged on the radiation-emerging side of the semiconductor layer sequence. The invention furthermore relates to a method for producing such semiconductor chips.

### BACKGROUND OF THE INVENTION

The semiconductor layers of semiconductor chips, for example the radiation-generating layer structures of radiation-emitting and of radiation-receiving semiconductor chips, can be defined by a multiplicity of different epitaxy methods, such as metal organic vapor phase epitaxy (MOVPE), molecular beam epitaxy (MBE), liquid phase epitaxy (LPE), etc. As an alternative or in a supplementary manner, such layer structures may at least partly be defined by indiffusion of dopants.

Both epitaxy processes and doping processes are subject to certain manufacturing fluctuations. In the case of light-emitting semiconductor chips, manufacturing fluctuations often lead to fluctuations in the brightness of semiconductor chips that are nominally of identical type, during operation. Both the wafers that are produced in different epitaxy process runs and the various wafers that are produced simultaneously in one process run are subject to manufacturing fluctuations, the fluctuations within the wafers produced in one process run being smaller.

During the production of a radiation-emitting semiconductor chip whose radiation emission can be set to a specific range during production, it is desirable if the epitaxy process that is subjected to great fluctuations due to its complexity can remain uninfluenced. The aim would thus be to be able to produce specific brightness classes of the radiation-emitting semiconductor chips without having to make process changes in the epitaxy process.

Taking account of this standpoint, semiconductor chips are known, for example, in which a brightness setting layer is arranged between a connection region and the active layer of the semiconductor chip, said brightness setting layer comprising at least one electrically insulating current blocking region and at least one electrically conductive current passage region. The current passage region electrically conductively connects the connection region and the semiconductor layer sequence to one another in such a way that current is injected into the semiconductor layer sequence below the connection region. Part of the electromagnetic radiation generated in the semiconductor chip is in this case generated below the connection region and is absorbed by the latter. The proportion of the radiation which is generated in the semiconductor chip and is not coupled out from the latter can be set by setting the size and position of the current passage region.

The brightness setting layer makes it possible, even from wafers with different brightnesses, such as may arise for example on account of fluctuations in the epitaxy and/or doping process or on account of fluctuations between different process runs, to produce semiconductor chips whose brightness lies comparatively reliably within a predetermined designed brightness range. With semiconductor layer sequences that are grown epitaxially in the same way, the structure described achieves semiconductor chips with brightnesses that are different in a targeted manner depending on the application.

One disadvantage of this procedure is that the production of the radiation-emitting semiconductor chip necessitates changed and additional masks compared with the standardized production process. The additional production steps bring about an undesirable increase in the production costs.

### SUMMARY OF THE INVENTION

One object of the invention is to provide a semiconductor structure the radiation emission of which can be set to a desired range during production in a simpler and more cost-effective manner than in the prior art.

A further object is to provide a method for producing such semiconductor chips.

These and other objects are attained in accordance with one aspect of the present invention directed to a radiation-emitting semiconductor chip having a semiconductor layer sequence comprising at least one active layer that generates an electromagnetic radiation, and having a passivation layer arranged on the radiation-emerging side of the semiconductor layer sequence, wherein the passivation layer is partly absorbent, it being possible to set the degree of transmission for the radiation emitted by the semiconductor layer sequence during operation of the semiconductor chip during the production of the passivation layer.

An aspect of the invention makes use of the fact that radiation-emitting semiconductor chips are often provided with an antireflection layer on the radiation-emerging side, by means of which an antireflection coating of the chip is effected. The degree of transmission of this passivation layer can be influenced, then, during application to the semiconductor layer sequence, which comprises at least one active layer that generates electromagnetic radiation, in terms of its composition. This means that depending on the composition of the passivation layer the degree of transmission can be set. The passivation layer can be set to a desired degree of transmission in this way.

In particular, the degree of transmission of the applied passivation layer can be set independently of the thickness of the passivation layer, for instance by means of its composition being influenced in a targeted manner and/or in a desired manner for a predetermined transmission. In this case, the thickness-independent transmission coefficient of the passivation layer can be set, in particular, by way of the composition of the passivation layer.

The passivation layer can comprise a dielectric material and has a volatile component, the degree of depletion of the volatile component during the production of the passivation layer influencing the transmission property of the passivation layer.

The passivation layer can be applied to the semiconductor layer sequence by means of a reactive sputtering method. Through the targeted depletion of a volatile component of the passivation material, e.g. O₂ or N₂, the degree of transmission of the passivation layer can be set in a continuously variable manner or in a virtually continuously variable manner.

In particular, a silicon nitride, such as SiN, a silicon oxide, such as SiO₂, an aluminum oxide, such as Al₂O₃, or a silicon oxynitride, such as SiON, is taken into consideration as material of the passivation layer.

As aspect of the invention is based on the principle of influencing the standardized step of applying a passivation layer, acting as an antireflection layer, with regard to the composition of the passivation material in order to cause the passivation layer to become partly absorbent and, consequently, the semiconductor chip to become darker. By means of a suitable process implementation, it is possible to bring about a continuously variable darkening of the semiconductor chip.

A semiconductor structure according to an aspect of the present invention makes it possible, with semiconductor layer sequences that are grown epitaxially in the same way, to produce semiconductor chips with, by way of example, brightnesses that are different in a targeted manner depending on the application. Therefore, it is advantageous that it is no longer totally necessary to use different epitaxy processes for producing semiconductor chips with different brightnesses. Consequently, an epitaxy installation can be operated with uniform process sequences to an increased extent, which contributes overall to stabilizing epitaxy processes.

In order to set chip batches within the desired brightness range, it is expedient rather to fabricate very bright chips which are then darkened to a uniform level that is desired depending on the application, after completion of the semiconductor layer sequence, by means of the passivation layer that is influenced in the manner according to the invention.

Another aspect of the present invention is directed to a radiation-emitting semiconductor chip having a semiconductor layer sequence comprising at least one active layer that generates an electromagnetic radiation, and having a passivation layer arranged on the radiation-emerging side of the semiconductor layer sequence, wherein the passivation layer comprises a brightness setting layer, which, during operation of the semiconductor chip, absorbs part of the electromagnetic radiation generated in the chip.

This aspect of the invention which comprises a brightness setting layer in the passivation layer makes it possible, in comparison with the chip structure known from the prior art, to use standardized production steps, only the last step of application of the passivation layer having to be slightly adapted. Without intervening in the epitaxy process, the brightness setting layer affords the possibility of varying the transmission of the passivation layer and, as a result, reducing the coupling-out of light. In this case, the degree of transmission can be set precisely in accordance with a desired specification.

The integration of the brightness setting layer in the passivation layer is effected in this case in such a manner that the function—intended by the passivation layer—of electrical insulation of the surface and the pn junction is not impaired in any way.

The brightness setting layer can be arranged between a first and a second layer of the passivation layer. In this case, the brightness setting layer may be formed from an amorphous silicon. The first and the second layer of the passivation layer preferably contain SiN, SiO or SiON.

The variation of the transmission of said passivation layer may be defined by the thickness of the brightness setting layer. In this case, the brightness setting layer is preferably formed by means of chemical vapor deposition, by means of which the thickness can be set by way of the duration of the treatment.

One advantage of this aspect of the invention is that the influencing of the degree of transmission at the semiconductor chip can be ascertained not by means of visual methods. The production of the brightness setting layer can be incorporated in a simple manner in the process of depositing the passivation layer. It is likewise advantageous that light that emerges from the mesa edge of the chip structure is likewise detected during production, thereby ensuring a homogeneous light adaptation.

The semiconductor structures according to an aspect of the invention make it possible to optimally coordinate the production of the semiconductor chips with changing customer requirements with regard to brightness or the light coupling-out efficiency. This reduces the risk of stock being formed by light classes that are not needed.

An aspect of the invention is thus based on the principle of influencing the absorption properties of dielectric layers in a targeted manner and of using them as absorbers for a radiation-emitting semiconductor chip.

In principle, an aspect of the invention is suitable for radiation-emitting semiconductor chips based on arbitrary semiconductor material systems suitable for radiation generation. The semiconductor chip, in particular the active layer, can contain a III-V semiconductor material, for instance a semiconductor material from the material systems InₓGa_{y}Al_{1-x-y}P, InₓGa_{y}Al_{1-x-y}N or InₓGa_{y}Al_{1-x-y}As, in each case where 0≦x≦1, 0≦y≦1 and x+y≦1. Such semiconductor materials are distinguished by advantageously high quantum efficiencies in the generation of radiation. InₓGa_{y}Al_{1-x-y}P, for example, is particularly suitable for radiation from the infrared through to the yellow or orange spectral range and InₓGa_{y}Al_{1-x-y}N is suitable for example for radiation from the green through to the ultraviolet spectral range.

The degree of transmission of a partly absorbent passivation layer can be set particularly efficiently in particular in the case of semiconductor chips based on semiconductor material systems which are suitable for generating radiation in the ultraviolet or visible spectral range.

### BRIEF DESCRIPTION OF THE DRAWINGS

FIG. 1 shows a diagrammatic illustration of a cross section through a semiconductor chip in accordance with a first variant,

FIG. 2 shows a diagrammatic illustration of a cross section through a semiconductor chip in accordance with a second variant,

FIG. 3 shows a table with different parameters for producing brightness setting layers with different degrees of transmission in accordance with the second variant, and

FIG. 4 shows a diagram revealing the relation between the degree of transmission and the layer thickness of the brightness setting layer in accordance with the second variant.

### DETAILED DESCRIPTION OF THE DRAWINGS

In the exemplary embodiments, identical or identically acting component parts are in each case designed identically and provided with the same reference symbols. The layer thicknesses illustrated are not true to scale. Rather, the illustration shows them with exaggerated thickness and not with the actual thickness ratios relative to one another, in order to afford a better understanding.

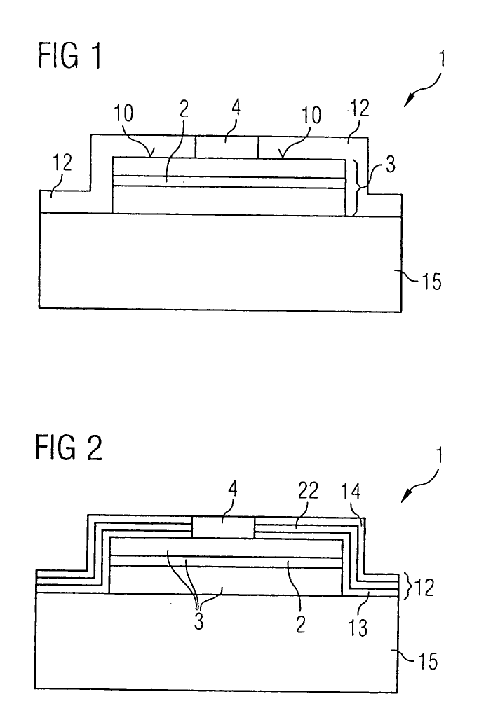

The exemplary embodiments illustrated in FIGS. 1 and 2 in accordance with a first and a second variant of the invention involve in each case a radiation-emitting semiconductor chip 1 having a semiconductor layer sequence 3 having an active layer 2 that generates electromagnetic radiation. Said active layer 2 may comprise an individual semiconductor layer or have a plurality of semiconductor layers which form a multiple quantum well structure for example.

A passivation layer 12 with a connection region 4 is in each case applied on the semiconductor layer sequence 3. The connection region 4 is a circular bonding pad for example. The connection region 4 may also have a different geometry, as required.

In accordance with the first variant according to FIG. 1, the passivation layer 12 represents an antireflection layer on the radiation-emerging side, which layer comprises a dielectric material, e.g. SiN, SiO₂, Al₂O₃, and by means of which an antireflection coating of the radiation-emitting semiconductor chip is effected. The degree of transmission of the semiconductor chip is set by means of the passivation layer during application thereof. The passivation layer is produced e.g. by means of a reactive sputtering method. In this case, elemental metal is removed from a metallic target and reacted through admixture of O₂ or N₂ to give the desired compound. The transparency of the antireflection layer can then be reduced through a targeted reduction of the required O₂ or N₂ partial pressure in the plasma of the sputtering coating. A pure, completely light-opaque metal layer can be deposited in the extreme case.

More generally speaking, it is proposed to deplete a volatile component of the antireflection material of the passivation layer during the coating process in a targeted manner in order to make the relevant passivation layer partly absorbent, as a result of which the semiconductor chip becomes darker. In principle, a continuously variable darkening of the radiation-emitting chip can be brought about by means of the process implementation during the production of the passivation layer.

In particular, the degree of transmission of the applied passivation layer can thus be set to the greatest possible extent independently of the thickness of the passivation layer by means of targeted influencing, for instance variation, of the composition of the passivation layer during its application. In particular, the thickness-independent transmission coefficient of the passivation layer can be set by way of the composition of the passivation layer.

The determination of the required depletion depends on the desired light output of the chip. In general, the smaller the amount of the volatile component which is present during the reactive sputtering process, the smaller the transmission. The following table shows the transmissions resulting from forming a passivation layer with different amounts of N2 being present during formation of a silicon nitride based passivation layer.

| N2-Flux | Transmission |
|---|---|
| [sccm] | [%] |
| 18.5 | 95% |
| 10 | 80% |
| 5 | 24% |
| Si (thickness 125 nm) | 16% |
| Si (thickness 500 nm) | 2% |

The amount of N2 which is present during the sputtering process is given by the N2 flux which is measured in sccm (standard cubic centimeters per minute), i.e. the higher the N2 flux the more N2 is present during sputtering. “Standard” means the flux at room temperature and a vaccuum pressure in the order of magnitude of 10\hat{ }(−2) mbar. In the last two lines of the table, no N2 is present at all and Si is sputtered from a Si-target on the chip.

Also, a semiconductor target may be used and, in particular, a pure semiconductor layer may be deposited from the semiconductor target.

The sputtering device used for the reactive sputtering process may be, for example, a LLS/BW device, which is commercially available.

The amount of depletion is controlled by reducing or raising the flux of the volatile component appropriately during the deposition process or by adjusting the flux of the volatile component before the deposition process is started appropriately to a fixed value, which value may be determined according to transmission measurements, for example, according to the table shown above.

In the case of the second variant of the invention in accordance with FIG. 2, the passivation layer 12 comprises a brightness setting layer 22, which is arranged by way of example between a first and a second layer 13, 14 of the passivation layer. In this case, the degree of transmission of the brightness setting layer can be defined by the thickness thereof.

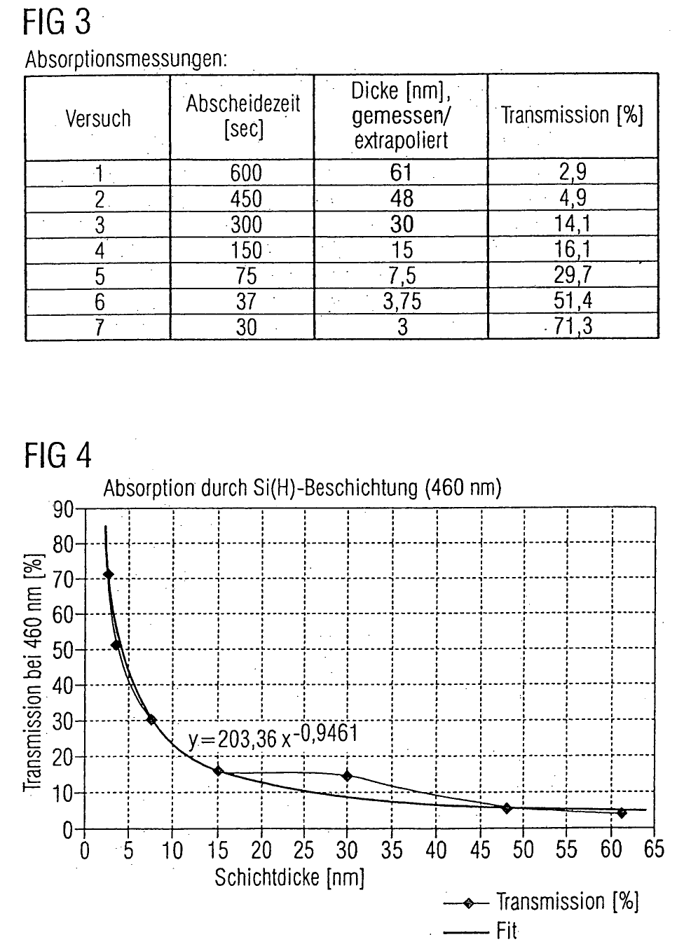

The thicknesses of the brightness setting layer that were obtained in the context of a plurality of experiments, in dependence on the deposition time of a plasma enhanced chemical vapor deposition (PECVD) can be gathered from the table in FIG. 3. As the deposition time increases, it is possible to obtain a larger thickness of the brightness setting layer. The relationship found between the layer thickness of the brightness setting layer and the degree of transmission at a wavelength of 460 nm can be seen from FIG. 4. The degree of transmission decreases approximately exponentially as the layer thickness increases.

For the experiments in accordance with the table in FIG. 3, the brightness setting layer was produced on a transparent substrate and then the transmission of the brightness setting layer of the respective experiment was determined at a wavelength of 460 nm.

The brightness setting layer 22 is preferably formed from amorphous PECVD silicon, while the first and second layers 13, 14 of the passivation layer 12 are formed from PECVD-SiN or SiO or SiON layers.

These PECVD layers are preferably deposited in a temperature range of 80° C. to 400° C. inclusive, a temperature range of 200° C. to 300° C. inclusive being particularly preferred. The pressure during deposition is, by way of example, between 0.5 and 4 torr inclusive. Process gases used during the production of the layers are, by way of example, SiH₄, He, N₂, N₂O and/or NH₃ in different mixing ratios.

A particular advantage of the invention is that the degree of transmission—which can be varied by means of the brightness setting layer—at the semiconductor chip can be ascertained not by means of visual methods. This also holds true, moreover, for the first variant with the passivation layer formed as an antireflection layer. As the brightness setting layer is part of the passivation layer and the passivation layer extends along the mesa edges of the chip, light emerging from the edges is transmitted through the brightness setting layer and hence this light may also be subjected to brightness setting in accordance with the desired light coupling out efficiency, so that the semiconductor chip overall has a homogeneous light emission characteristic.

The actual function of electrical insulation of the surface and the pn junction is not influenced in the case of both variants in accordance with FIGS. 1 and 2 despite modifications in comparison with a conventional semiconductor structure. Both variants permit a process-compatible integration of the process steps respectively required during the passivation process carried out in standard fashion for forming the passivation layer.

The invention is not restricted by the description on the basis of the exemplary embodiments. Rather, the invention encompasses any new feature and also any combination of features, which, in particular, comprises any combination of features in the patent claims even if this feature or this combination itself is not specified explicitly in the patent claims or exemplary embodiments.

1. A radiation-emitting semiconductor chip (1) having a semiconductor layer sequence (3) comprising at least one active layer (2) that generates an electromagnetic radiation, and having a passivation layer (12) arranged on the radiation-emerging side of the semiconductor layer sequence (3),
wherein
the passivation layer (12) is partly absorbent, it being possible to set the degree of transmission for the radiation emitted by the semiconductor layer sequence during operation of the semiconductor chip (1) during the production of the passivation layer (12).

2. The semiconductor chip as claimed in claim 1,
wherein
the passivation layer (12) comprises a dielectric material and has a volatile component, the degree of depletion of the volatile component during the production of the passivation layer (12) influencing the transmission property of the passivation layer (12).

3. The semiconductor chip as claimed in claim 1,
wherein
the degree of transmission of the passivation layer (12) can be set in a continuously variable manner or in a virtually continuously variable manner.

4. The semiconductor chip as claimed in claim 1,
wherein
the passivation layer (12) contains SiN, SiO₂, Al₂O₃ or SiON.

5. A radiation-emitting semiconductor chip (1) having a semiconductor layer sequence (3) comprising at least one active layer (2) that generates an electromagnetic radiation, and having a passivation layer (12) arranged on the radiation-emerging side of the semiconductor layer sequence (3),
wherein
the passivation layer (12) comprises a brightness setting layer (22), which, during operation of the semiconductor chip (1), absorbs part of the electromagnetic radiation generated in the chip.

6. The semiconductor chip as claimed in claim 5,
wherein
the passivation layer (12) has a first and a second layer (13, 14) and the brightness setting layer (22) is arranged between the first and the second layer (13, 14).

7. The semiconductor chip as claimed in claim 5,
wherein
the degree of transmission of the brightness setting layer (22) is defined by the thickness of the brightness setting layer (22).

8. The semiconductor chip as claimed in claim 5,
wherein
the brightness setting layer (22) is formed with amorphous silicon.

9. The semiconductor chip as claimed in claim 4,
wherein
the first and the second layer (13, 14) of the passivation layer (12) contain SiN, SiO or SiON.

10. A method for producing a semiconductor chip as claimed in claim 1, having the following steps:
production of the semiconductor layer sequence (3) with an active layer (2) on a substrate (15);
application of a partly absorbent passivation layer (12) on the radiation-emerging side of the semiconductor layer sequence (3), the degree of transmission of the passivation layer (12) being set during application of the passivation material by way of the composition of the passivation material.

11. The method as claimed in claim 10,
wherein
the passivation layer (12) is applied by means of a reactive sputtering method.

12. The method as claimed in claim 10,
wherein
a volatile component of the passivation material is depleted in a targeted manner during application of the passivation layer (12).

13. A method for producing a semiconductor chip as claimed in claim 5, having the following steps:
production of the semiconductor layer sequence (3) with an active layer (2) on a substrate (15); and
application of a passivation layer (12), a brightness setting layer (22) being formed in the passivation layer.

14. The method as claimed in claim 13,
wherein
the application of the passivation layer comprises the formation of the following layer sequence:
a first layer (13) made of a first dielectric material on the radiation-emerging side of the semiconductor layer sequence (3);
the brightness setting layer (22) made of a second dielectric material on the first layer (13); and
a second layer (14) made of the first dielectric material on the brightness setting layer (22).

15. The method as claimed in claim 13,
wherein
the brightness setting layer (22) is formed by means of chemical vapor deposition.
